(19) United States
(12) Patent Application Publication
(10) Pub. No.: US 2025/0380556 A1
(43) Pub. Date: Dec. 11, 2025

(54) LIGHT EMITTING APPARATUS

(71) Applicant: Seoul Semiconductor Co., Ltd., Ansan-si (KR)

(72) Inventor: Sewon TAE, Ansan-si (KR)

(73) Assignee: Seoul Semiconductor Co., Ltd., Ansan-si (KR)

(21) Appl. No.: 19/232,475

(22) Filed: Jun. 9, 2025

Related U.S. Application Data
(60) Provisional application No. 63/658,085, filed on Jun. 10, 2024.

(51) Int. Cl. H10H 29/855; H10H 29/14; H10H 29/853; H10H 29/856

(52) U.S. Cl. CPC H10H 29/855; H10H 29/142; H10H 29/853; H10H 29/8552; H10H 29/856

(57) ABSTRACT

A light emitting apparatus may include a housing having a cavity open at an upper side thereof, a light source disposed in the cavity of the housing and emitting light, and a lens disposed on the housing and including a light incidence and a light exit. The lens may include a first optical region comprising a curved surface having a diameter gradually decreasing from bottom to top and a second optical region disposed under the first optical region, the second optical region having a flat side surface. A maximum diameter of the first optical region is less than or equal to a maximum diameter of the second optical region. A light beam angle of the lens is narrower than a light beam angle of the light source, and the light beam angle of the lens is less than 90 degrees.

### CROSS-REFERENCE TO RELATED APPLICATIONS

The present application is a non-provisional Application which claims priority to the benefit of U.S. Provisional Application No. 63/658,085 filed Jun. 10, 2024, the disclosure of which is incorporated by reference herein in its entirety.

### BACKGROUND

### Field

The present invention relates to a light emitting apparatus.

### Discussion of the Background

A light emitting diode is a semiconductor device that emits light through recombination of electrons and holes, and has recently been used in many fields, such as displays, vehicular lamps, general lighting, and the like. With advantages of long lifespan, low power consumption, and fast response, light emitting diodes are applied to various fields, such as vehicular lamps, displays, and the like. For example, light emitting diodes are also applied to head-mounted displays (HMDs) and are widely applied to vehicular headlamps due to their excellent straightness of light.

However, a light emitting diode fails to realize uniform luminance on a light exit surface for a variety of reasons.

Moreover, precise control of light irradiation requires that each light emitting diode or light emitting device, such as a chip or a package, including the light emitting diode, has a narrow beam angle.

### SUMMARY

Embodiments of the present invention provide a lens capable of realizing a narrow beam angle, and a light emitting package and a light emitting apparatus including the same.

Embodiments of the present invention provide a lens capable of realizing a narrow beam angle and improving luminance uniformity, and a light emitting package and a light emitting apparatus including the same.

Embodiments of the present invention provide a light emitting package and a light emitting apparatus with high luminance.

In accordance with one aspect of the present invention, there is provided a lens including a light incidence surface through which external light enters the lens and a light exit surface through which the light having entered the lens exits the lens. The lens may include a first optical region and a second optical region. The first optical region may include a curved surface having a diameter gradually decreasing from bottom to top. The second optical region may be disposed under the first optical region, may have a constant width from top to bottom and may include a flat side surface. A maximum diameter of the first optical region may be less than or equal to a maximum diameter of the second optical region. A part or all of a lower surface of the second optical region may constitute the light incidence surface. An outer surface of the first optical region may constitute the light exit surface. In addition, the lens may have a light bean angle of less than about 90 degrees.

The first optical region may include a first curved surface and a second curved surface disposed between the first curved surface and the second optical region. The first curved surface may include a convexly curved surface having a diameter gradually decreasing from bottom to top. In addition, the second curved surface may include a concavely curved surface having a diameter gradually increasing from top to bottom.

The second optical region may have a lower height than the first optical region.

The height of the second optical region may be less than or equal to about 60% of the height of the first optical region.

A lower end of an inner surface of the first optical region may have the same diameter as an upper end of an inner surface of the second optical region.

The second optical region may include a light absorbing material or a light reflecting material in at least a region thereof excluding the light incidence surface.

The first optical region and the second optical region may be integrally formed with each other.

The first optical region may have an outer shape according to Formula 1:

$$y = a + b \sqrt{c - {x}^{2}} \qquad ( 1 )$$

where x is a position on the lens along the x-axis of the lens, y is the height of the lens depending on the position x, a is the height of the second optical region, b is a ratio of the height of the first optical region to the radius thereof, and \sqrt{c} is the radius of the first optical region.

In accordance with another aspect of the present invention, there is provided a light emitting package including a housing, a light source, and a lens. The housing may include a cavity open at an upper side thereof. The light source may be disposed in the cavity of the housing, and may generate and emit light. The lens may be disposed on the housing and may include a light incidence surface through which external light enters the lens and a light exit surface through which the light having entered the lens exits the lens. The lens may include a first optical region and a second optical region. The first optical region may include a curved surface having a diameter gradually decreasing from bottom to top. The second optical region may be disposed under the first optical region, may have a constant width from top to bottom, and may include a flat side surface. A maximum diameter of the first optical region may be less than or equal to a maximum diameter of the second optical region. A part or all of a lower surface of the second optical region may constitute the light incidence surface. An outer surface of the first optical region may constitute the light incidence surface. The lens may have a smaller beam angle than the light source. In addition, the light beam angle of the lens may be less than about 90 degrees.

The first optical region may include a first curved surface and a second curved surface disposed between the first curved surface and the second optical region. The first curved surface may include a convexly curved surface having a diameter gradually decreasing from bottom to top. In addition, the second curved surface may include a concavely curved surface having a diameter gradually increasing from top to bottom.

An uppermost end of the first optical region of the lens may be disposed on a vertical line collinear with a center of the light source.

A height of the first optical region of the lens may be in the range of about 1 to about 2.5 times a height of the housing.

A height of the second optical region may be less than a height of the first optical region and greater than a height of the light source.

The height of the second optical region may be less than or equal to about 60% of the height of the first optical region.

The height of the second optical region of the lens may be greater than or equal to about 6 times and less than about 10 times the height of the light source.

A lower end of an inner surface of the first optical region may have the same diameter as an upper end of an inner surface of the second optical region.

The second optical region may include a light absorbing material or a light reflecting material in at least a region thereof excluding the light incidence surface.

The first optical region and the second optical region may be integrally formed with each other.

The light emitting package may further include a molding region formed in the cavity of the housing and covering the light source. The molding region may be formed of a material allowing transmission of light emitted from the light source therethrough.

The first optical region may have an outer shape according to Formula 1:

$$y = a + b \sqrt{c - {x}^{2}} \qquad ( 1 )$$

where x is a position on the lens along the x-axis of the lens, y is the height of the lens depending on the position x, a is the height of the second optical region, b is a ratio of the height of the first optical region to the radius thereof, and \sqrt{c} is the radius of the first optical region.

In accordance with a further aspect of the present invention, there is provided a light emitting apparatus including: a light emitting package array including a plurality of light emitting packages; and a support on which the light emitting package array is mounted. Each of the plurality of light emitting packages may include a housing, a light source, and a lens. The housing may include a cavity open at an upper side thereof. The light source may be disposed in the cavity of the housing, and may generate and emit light. The lens may be disposed on an upper side of the housing and may include a light incidence surface through which external light enters the lens and a light exit surface through which the light having entered the lens exits the lens. The lens may include a first optical region and a second optical region. The first optical region may include a curved surface having a diameter gradually decreasing from bottom to top. The second optical region may be disposed under the first optical region, may have a constant width from top to bottom, and may include a flat side surface. A maximum diameter of the first optical region may be less than or equal to a maximum diameter of the second optical region. A part or all of a lower surface of the second optical region may constitute the light incidence surface. An outer surface of the first optical region may constitute the light incidence surface. The light emitting package may have a smaller beam angle than the light source. In addition, the light beam angle of the light emitting package may be less than about 90 degrees.

A height of the first optical region of the lens may be in the range of about 1 to about 2.5 times a height of the housing.

A height of the second optical region may be less than a height of the first optical region and greater than a height of the light source.

The height of the second optical region may be less than or equal to about 60% of the height of the first optical region.

The height of the second optical region of the lens may be greater than or equal to about 6 times and less than about 10 times the height of the light source.

The second optical region may include a light absorbing material or a light reflecting material in at least a region thereof excluding the light incidence surface.

The first optical region may have an outer shape according to Formula 1:

$$y = a + b \sqrt{c - {x}^{2}} \qquad ( 1 )$$

where x is a position on the lens along the x-axis of the lens, y is the height of the lens depending on the position x, a is the height of the second optical region, b is a ratio of the height of the first optical region to the radius thereof, and \sqrt{c} is the radius of the first optical region.

Embodiments of the present invention provide a lens capable of realizing a narrower beam angle than a light source and a light emitting package including the same.

Embodiments of the present invention provide a lens capable of improving luminance uniformity, and a light emitting package and a light emitting apparatus including the same.

### BRIEF DESCRIPTION OF THE DRAWINGS

FIG. 1 is a cross-sectional view of a lens according to an embodiment of the present invention.

FIG. 2 is an enlarged view of part A of the lens of FIG. 1.

FIG. 3 is a plan view of the lens according to the embodiment of the present invention.

FIG. 4 is a cross-sectional view of a light emitting package according to a first embodiment of the present invention.

FIG. 5 is a light distribution graph depicting light distribution of the light emitting package of FIG. 4.

FIG. 6 is a cross-sectional view of a light emitting package according to a second embodiment of the present invention

FIG. 7 is a light distribution graph depicting light distribution of the light emitting package of FIG. 6.

FIG. 8 is a cross-sectional view of a light emitting package according to a third embodiment of the present invention

FIG. 9 is a light distribution graph depicting light distribution of the light emitting package of FIG. 8.

FIG. 10 is a cross-sectional view of a light emitting package according to a fourth embodiment of the present invention.

FIG. 11 is a light distribution graph depicting light distribution of the light emitting package of FIG. 10.

FIG. 12 is a plan view of a light emitting apparatus according to an embodiment of the present invention.

FIG. 13 shows simulation results of illuminance of the light emitting apparatus shown in FIG. 12.

FIG. 14 is an exemplary view of a vehicle including a light emitting apparatus according to an embodiment of the present invention.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

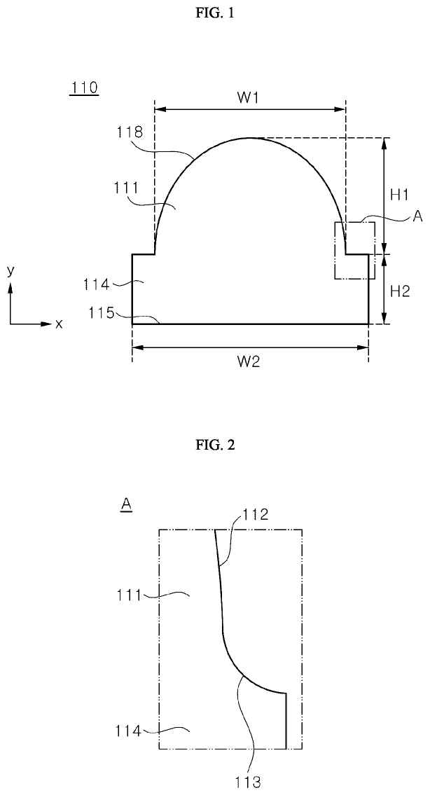

Hereinafter, a lens according to the present invention and light emitting packages and light emitting apparatuses including the same will be described in detail with reference to the drawings. FIG. 1 to FIG. 3 show a lens according to an embodiment of the present invention.

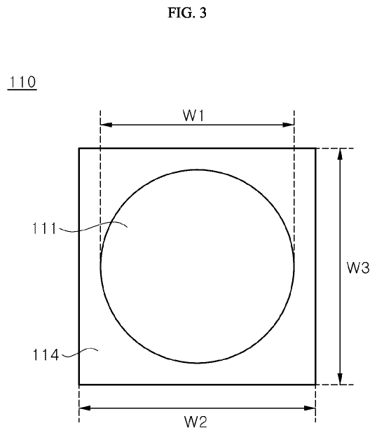

FIG. 1 is a cross-sectional view of a lens according to an embodiment of the present invention. FIG. 2 is an enlarged view of part A of the lens of FIG. 1. FIG. 3 is a plan view of the lens according to the embodiment of the present invention.

According to this embodiment, the lens 110 includes a light incidence surface 115 through which light emitted from a light source enters the lens 110 and a light exit surface 118 through which light having entered the lens 110 is emitted from the lens 110.

Referring to FIG. 1 and FIG. 2, the lens 110 according to the embodiment may include a first optical region 111 and a second optical region 114.

The first optical region 111 may be disposed on the second optical region 114.

According to this embodiment, the first optical region 111 may include a convexly curved surface having a diameter gradually decreasing from bottom to top.

Referring to FIG. 2, the first optical region 111 may include a first curved surface 112 and a second curved surface 113. The first curved surface 112 of the first optical region 111 may be disposed on the second curved surface 113. The second curved surface 113 of the first optical region 111 may be disposed between the first curved surface 112 and the second optical region 114. That is, an upper end of the second curved surface 113 may be connected to a lower end of the first curved surface 112 and a lower end of the second curved surface 113 may be connected to an upper end of the second optical region 114.

Referring to FIG. 2, the first curved surface 112 of the first optical region 111 may include a curved surface having at least a convexly curved region, which has a diameter gradually decreasing from bottom to top. For example, the first curved surface 112 may have a dome shape. The diameter and curvature of the first curved surface 112 may be determined in consideration of the light beam angle. Here, the beam angle refers to an angle within which a luminous intensity is greater than or equal to 50% of a peak luminous intensity of the light emitting package.

In addition, the second curved surface 113 may include a curved surface having at least a concavely curved region, which has a diameter gradually increasing from top to bottom.

A curved surface of the second curved surface 113 may become a corner connecting the first curved surface 112 and the second optical region 114, which have different diameters. Since the corner of the second curved surface 113 is the curved surface, the lens 110 according to this embodiment can relieve stress generated at the corner. Accordingly, the lens 110 according to this embodiment can suppress breakage due to external impact by the second curved surface 113 including the curved surface.

FIG. 2 shows that the entirety of the second curved surface 113 is concave. However, it should be understood that the present invention is not limited thereto. For example, the second curved surface 113 may be curved at the corner thereof, at which stress is concentrated, and may be flat in the remaining region thereof.

The first optical region 111 may include a light exit surface 118 of the lens 110. That is, an outer surface of the first optical region 111 may constitute the light exit surface 118 of the lens 110 through which light having entered the lens 110 is emitted to the outside.

Referring to FIG. 1, the second optical region 114 may have a constant width from top to bottom or a constant cross-sectional area. That is, the second optical region 114 may have a constant width from top to bottom and may include flat side surfaces. Referring to FIG. 3, the first optical region 111 may be formed to have a circular perimeter and the second optical region 114 may be formed to have a square perimeter in plan view. By way of example, a longitudinal width W2 (FIG. 3) of the second optical region 114 may be the same as a transverse width W3 (FIG. 3) thereof in plan view.

Referring to FIG. 1 and FIG. 3, the widths W2, W3 of the second optical region 114 may be greater than a diameter W1 of the first optical region 111. Here, the widths W2, W3 of the second optical region 114 corresponds to the longitudinal width W2 or the transverse width W3 of the perimeter of the second optical region 114 in plan view. In addition, the diameter W1 of the first optical region 111 corresponds to a diameter of the perimeter of the first optical region 111 in plan view. For example, the widths W2, W3 of an upper surface of the second optical region 114 may be greater than the diameter W1 of a lower end of the first optical region 111, which has the greatest diameter. Since the widths W2, W3 of the second optical region 114 are greater than the diameter W1 of the first optical region 111, the lens 110 according to this embodiment has high structural stability.

However, the lens 110 according to this embodiment is not limited to the structure in which the widths W2, W3 of the second optical region 114 are greater than the diameter W1 of the lower end of the first optical region 111. Alternatively, the widths W2, W3 of the second optical region 114 may be the same as the diameter W1 of the lower end of the first optical region 111. That is, in the lens 110 according to this embodiment, the widths W2, W3 of the second optical region 114 may be greater than or equal to the maximum diameter W1 of the first optical region 111. In addition, a diagonal length of the second optical region 114 may be greater than the maximum diameter W1 of the first optical region 111.

In addition, the second optical region 114 may have a larger cross-sectional area than the first optical region 111. More specifically, an area defined by the perimeter of the second optical region 114 may be larger than an area defined by a lower perimeter of the first optical region 111 in plan view.

Further, a height H2 of the second optical region 114 may be less than a height H1 of the first optical region 111. For example, the height H2 of the second optical region 114 may be greater than or equal to about 15% and less than or equal to about 60% of the height H1 of the first optical region 111. When the height H2 of the second optical region 114 is less than or equal to about 60% of the height H1 of the first optical region 111, light loss by the second optical region 114 can be reduced. In addition, when the height H2 of the second optical region 114 is greater than or equal to about 15% of the height H1 of the first optical region 111, the center of gravity of the lens 110 can be lowered to prevent the lens 110 from moving or falling off of the light emitting package or the light emitting apparatus. Accordingly, structural stability of the light emitting package or the light emitting apparatus in which the lens 110 is mounted can be improved. Here, the height H2 of the second optical region 114 corresponds to a length from the upper surface of the second optical region 114 to a lower surface of the second optical region 114. Further, the height H1 of the first optical region 111 corresponds to a length from the uppermost end of the first optical region 111 to the lower end of the first optical region 111 in the vertical direction.

A curved shape corresponding to an outer shape of the first optical region 111 of the lens 110 according to this embodiment may be defined according to the following Formula 1. That is, the first optical region 111 of the lens 110 may have a dome shape according to Formula 1:

$$y = a + b \sqrt{c - {x}^{2}} \qquad ( 1 )$$

where x is a position on the lens 110 along the x-axis of the lens, y is a height of the lens depending on the position x, a is the height H2 of the second optical region 114, b is a ratio of the height H1 to 0.5 times the longitudinal width W1 (that is, the radius) of the first optical region 111, and \sqrt{c} is the radius of the first optical region 111 that is 0.5 times the longitudinal width W1 of the first optical region 111. Here, b may be greater than or equal to 1.

According to this embodiment, the lens 110 may have a total height (H1+H2) represented by Formula 2:

$$H 1 + H 2 = a + b \sqrt{c} \qquad ( 2 )$$

where a is the height H2 of the second optical region 114 and b\sqrt{c} is the height H1 of the first optical region 111.

Since the height H2 of the second optical region 114 is less than the height H1 of the first optical region 111, a may be smaller than b\sqrt{c}. As the height H1 of the first optical region 111 increases relative to the total height (H1+H2) of the lens 110, the height H2 of the second optical region 114 decreases. Here, an increase in the height H1 of the first optical region 111 can reduce the beam angle of the lens and a decrease in the height H2 of the second optical region 114 can reduce light loss through reduction of a straight region.

A lower center of the first optical region 111 may be placed at (0, a). An emission direction of light passing through the lens 110 may be adjusted by changing the height of the lower center of the first optical region 111. That is, the emission direction of the light passing through the lens 110 may be adjusted by changing the height of the second optical region 114.

A reference point where the x-axis and the y-axis meet each other may be placed at (0, 0), which corresponds to a center of an inner region of a lower perimeter of the lens 110. A height of the curved surface at each region, which is the outer surface of the first optical region 111, may be represented by (x, y). That is, the shape of the first optical region 111 of the lens 110 according to the first embodiment may be derived by connecting a plurality of points (x, y) according to Formula 1.

Since the first optical region 111 of the lens 1110 has a dome shape according to Formula 1, the lens may have a similar light emission path in any direction in which light is emitted. Thus, the lens 110 according to this embodiment can improve light uniformity.

The lower surface of the second optical region 114, which corresponds to a lower surface of the lens 110, is the light incidence surface 115 through which light emitted from a light source disposed below the lens 110 enters the lens 110.

In addition, the second optical region 114 may include a light absorbing material or a light reflecting material in a region thereof. The region of the second optical region 114 including the light absorbing material or the light reflecting material may be a partial or entire region thereof excluding the light incidence surface. Here, the amount of light emitted through the side surfaces of the second optical region 114 can be reduced by adjusting a position of the region containing the light absorbing material or the light reflecting material. Accordingly, the beam angle of the lens 110 can be further narrowed.

According to this embodiment, the first curved surface 112, the second curved surface 113, and the second optical region 114 may be integrally formed with each other. In this structure, the interfaces therebetween can be further reduced, thereby reducing a moisture penetration path, compared to a structure wherein the first curved surface 112, the second curved surface 113, and the second optical region 114 are separately formed and then bonded together to form the lens 110. Accordingly, moisture penetration through the lens 110 can be delayed, thereby improving reliability of the lens 110 and a package including the lens 110.

However, it should be understood that the lens 110 according to the present invention is not limited to such a monolithic structure and may have a structure wherein at least one of the first curved surface 112, the second curved surface 113, or the second optical region 114 is separately formed and then bonded to the other components. In this embodiment, the components of a simple structure constituting the lens 110 may be separately formed. Then, the components of the simple structure may be bonded together to form the lens 110 with a complex structure. Since the individually formed components have a simple structure, the components can be easily formed by a simple process. That is, the components formed by the simple process may be used to form the lens 110 with a complex structure. Thus, the process of forming the lens 110 can be simplified, thereby improving productivity of the lens 110.

In addition, the lens 110 may be formed of a light transmissive material, such as a silicone resin, an epoxy resin, glass, a urethane resin, methyl methacrylate (MMA), a polystyrene resin, an allyl diglycol carbonate resin, a polycarbonate resin, polymethyl methacrylate (PMMA), Fluoropolymer, and the like.

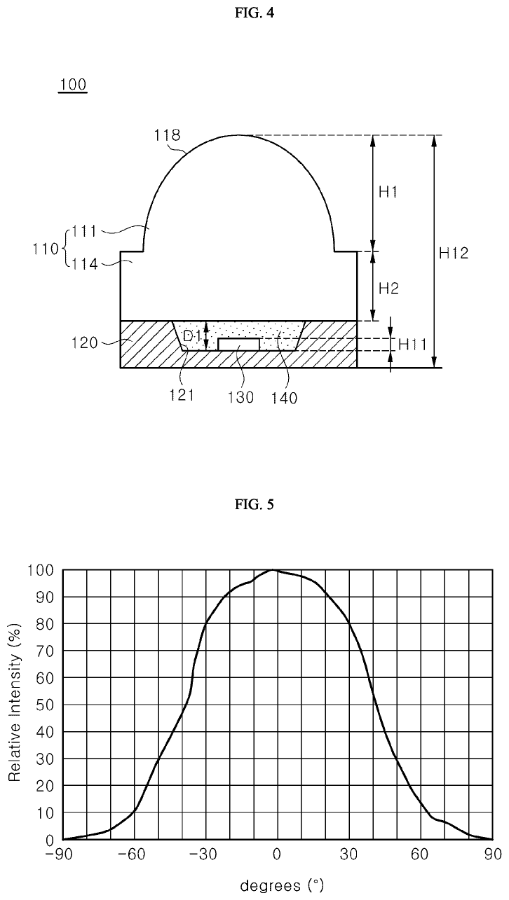

FIG. 4 and FIG. 5 illustrate a light emitting package according to a first embodiment of the present invention. FIG. 4 is a cross-sectional view of the light emitting package according to the first embodiment of the present invention. FIG. 5 is a light distribution graph depicting light distribution of the light emitting package of FIG. 4.

Referring now to FIG. 4, the light emitting package 100 according to the first embodiment may include a housing 120, a light source 130, an encapsulation material 140, and a lens 110.

The housing 120 may include a cavity 121 having a predetermined depth from an upper surface of the housing 120 in a downward direction. According to this embodiment, a depth D1 of the cavity 121 may be greater than a height H11 of the light source 130. Here, the height of the light source 130 corresponds to a length from an upper surface of the light source 130 to a lower surface thereof. That is, the upper surface of the light source 130 may be placed below the upper surface of the housing 120. In addition, an inner wall of the housing 120 defining the cavity 121 may include an inclined surface to reflect light emitted from the light source 130 in an upward direction.

The housing 120 may be formed of a variety of insulating materials. For example, the housing 120 may include a ceramic resin, an epoxy resin, or a polymer resin, such as a silicone resin, a polyimide resin, a urethane resin, and the like. The housing 120 may further include fillers for reflecting or scattering light. For example, the fillers may include titanium oxide (TiO₂), silicon oxide (SiO₂), zirconium oxide (ZrO₂), or the like.

Although not shown in the drawings, the housing 120 may be supported by lead frames electrically connected to the light source 130 mounted in the cavity 121. The lead frames may extend from the cavity 121 of the housing 120 to the outside of the housing 120.

The light source 130 is mounted in the cavity 121 of the housing 120. The light source 130 may be powered through the lead frames electrically connected thereto to generate and emit light. According to this embodiment, the light source 130 may include a light emitting diode formed of a compound semiconductor. Further, the light emitting diode applied to the light source 130 may have any structure among a vertical structure, a horizontal structure, and a flip-chip structure. For example, the light source 130 may be a light emitting diode chip including a light emitting diode.

In this embodiment, a single light source 130 is mounted in the cavity 121 of the housing 120. Alternatively, a plurality of light sources 130 may be mounted therein, as needed. Here, all of the plurality of light sources 130 may emit light in the same wavelength range, or at least a light source 130 may emit light in a different wavelength range than the other light sources 130. That is, all of the plurality of light sources 130 may emit light of the same color or at least a light source 130 may emit light of a different color than the other light sources 130.

The encapsulation material 140 may be disposed to fill the cavity 121 of the housing 120 such that the light source 130 is covered therewith. Since the depth D1 of the cavity 121 of the housing 120 is greater than the height H1 of the light source 130, the encapsulation material 140 may be formed on the light source 130 to have a predetermined thickness. The encapsulation material 140 may be formed of a light transmissive material, such as a silicone resin or an epoxy resin, through which light emitted from the light source 130 is transmitted.

The light emitting package 100 according to this embodiment may further include a wavelength conversion material capable of generating light of a specific color using light emitted from the light source 130 as an excitation source. The wavelength conversion material may be selected from any materials, which can absorb light and emit light of a specific color, such as phosphors, quantum dots, or organic dies.

The wavelength conversion material may be dispersed in the encapsulation material 140. Alternatively, the light emitting package 100 may further include a wavelength converter covering the light source 130 or formed on the light source 130. The wavelength converter may include a carrier formed of a polymer resin, glass, or a ceramic material, such as alumina, and a wavelength conversion material dispersed in the carrier. For example, when the light source 130 emits blue light, the wavelength conversion material may emit yellow green light or yellow light using a fraction of the blue light as an excitation source such that the light emitting package 100 can emit white light as a mixture of these colors. However, it should be understood that the present invention is not limited thereto and colors of light emitted from the light source 130 and light emitted from the wavelength conversion material may be varied depending on the color of light to be emitted from the light emitting package 100. In addition, various types of wavelength conversion materials may be applied thereto.

The lens 110 may be disposed on the housing 120. The lens 110 according to this embodiment includes the lens 110 described with reference to FIG. 1 to FIG. 3. The lens 110 may be bonded to an upper surface of the housing 120 using a bonding agent.

According to this embodiment, since the lens 110 is mounted on the upper surface of the housing 120, a separation distance between the light source 130 and the lens 110 may be adjusted depending on the depth of the cavity 121 of the housing 120.

In the light emitting package 100 according to this embodiment, the uppermost end of the first optical region 111 of the lens 110 may be disposed on the vertical line collinear with the center of the light source 130. That is, the center of the lens 110 and the center of the light source 130 may be disposed on the same vertical line. Furthermore, the height H1 of the first optical region 111 of the lens 110 may be in the range of about 1 to about 2.5 times a height of the housing 120.

In addition, an outer perimeter of the lower surface of the lens 110 having the greatest diameter may be disposed outside the light source 130.

Further, the height H2 of the second optical region 114 of the lens 110 may be greater than or equal to about 6 times and less than about 10 times the height H11 of the light source 130.

According to the embodiment, since the widths W2, W3 (see FIG. 3) of the second optical region 114 are greater than the diameter W1 (see FIG. 3) of the first optical region 111, the lens 110 has high structural stability. Thus, the light emitting package 100 can suppress failure of separation of the lens 110 from the housing 120 due to external impact.

In addition, the total height H1+H2 (see FIG. 1) of the lens 110 may be in the range of about 0.5 times to about 1.1 times a major axis length of the light emitting package 100. Further, the total height of the lens 110 may be in the range of about 0.6 times to about 1.3 times a minor axis length of the light emitting package 100. Here, among longitudinal and transverse lengths of a horizontal cross-section of the light emitting package 100, a longer length corresponds to the major axis length of the light emitting package 100 and a shorter length corresponds to the minor axis length of the light emitting package 100. In addition, the horizontal cross-section of the light emitting package 100 corresponds to a cross-section parallel to the upper or lower surface of the light emitting package 100. the major axis length of the light emitting package 100 may be the same as a length of a major axis length of the housing 120. Further, the minor axis length of the light emitting package 100 may be the same as a length of a minor axis length of the housing 120. In other words, the total height of the lens 110 may be equal to or greater than about 0.5 times and equal to or less than about 1.1 times the major axis length of the housing 120. And also, the total height of the lens 110 may be equal to or greater than about 0.6 times and equal to or less than about 1.3 times the minor axis length of the housing 120. Further, the total height of the lens 110 may be equal to or greater than about 1 times and equal to or less than about 2.5 times a height of the housing 120.

Referring to FIG. 5, the light emitting package 100 according to the first embodiment may have a peak luminous intensity at an angle of 0 degrees or at an angle close to 0 degrees relative to a front side thereof. In other words, a point where the luminous intensity reaches a maximum value relative to an optical axis of the light emitting diode may be disposed on a vertical centerline of the light source 130. Here, the peak luminous intensity may be greater than or equal to about 30 cd and less than or equal to about 40 cd. For example, the light emitting package 100 may have a peak luminous intensity of about 35.873 cd (lm/sr). In addition, the light emitting package 100 according to the first embodiment may have an angle range of about −42 degrees to about 42 degrees, at which the light emitting package 100 has a luminous intensity of greater than or equal to about 50% of the peak luminous intensity. More specifically, the light emitting package 100 according to the first embodiment may have a light beam angle of about 83.6 degrees.

Furthermore, the light emitting package 100 according to the first embodiment may have an angle range of about −30 degrees to about 30 degrees, at which the light emitting package 100 has a luminous intensity of greater than or equal to about 80% of the peak luminous intensity. That is, the light emitting package 100 according to the first embodiment may emit about 80% or more of light (luminous flux) emitted therefrom at an angle of about 60 degrees relative to a central axis perpendicular to the lower surface of the light emitting package 100. As such, the light emitting package according to the first embodiment can improve luminance of a display device.

Furthermore, a plurality of light emitting packages 100 according to the first embodiment may be arranged in the display device. Here, since the light emitting packages 100 emit light intensively within a certain range, the light emitting packages 100 may have a lower luminous intensity deviation than light emitting packages having lower luminous intensities within the certain range. Accordingly, the light emitting package 100 may have a lower illuminance deviation and/or a lower luminance deviation than light emitting packages having lower luminous intensity within a certain range. For example, a difference between the luminous intensity in an overlapping region where light emitted from at least two light emitting packages 100 overlaps and the luminous intensity in a central region of each of the light emitting packages 100 may be less than about 40%. That is, a difference in illuminance and/or luminance between the overlapping region of the light emitting packages 100 and the central region of each light emitting package 100 may be less than about 40%. Thus, the illuminance and/or luminance in the overlapping region of the light emitting package 100 may be greater than or equal to about 60% of the illuminance and/or luminance in the central region of the light emitting package 100. Furthermore, the light emitting packages 100 according to this embodiment may have a lower luminous intensity deviation, illuminance deviation and/or luminance deviation than light emitting packages having a wider beam angle and a larger overlapping region between neighboring light emitting packages than the light emitting package according to this embodiment. As such, the light emitting packages 100 according to this embodiment have a lower luminous intensity deviation, illuminance deviation and/or luminance deviation within an effective region, thereby improving uniformity in illuminance and/or luminance of a display device.

Furthermore, at an angle range of 60 degrees relative to the central axis, the light emitting packages 100 according to this embodiment may have a luminous intensity of about 80% or more. Here, the light emitting packages 100 according to this embodiment may have a luminous intensity deviation of about 20% or less. That is, the light emitting packages 100 according to this embodiment may have a maximum luminous intensity deviation of about 20%.

As such, the light emitting package 100 according to this embodiment can improve luminance of the display device and reduces luminance deviation by region.

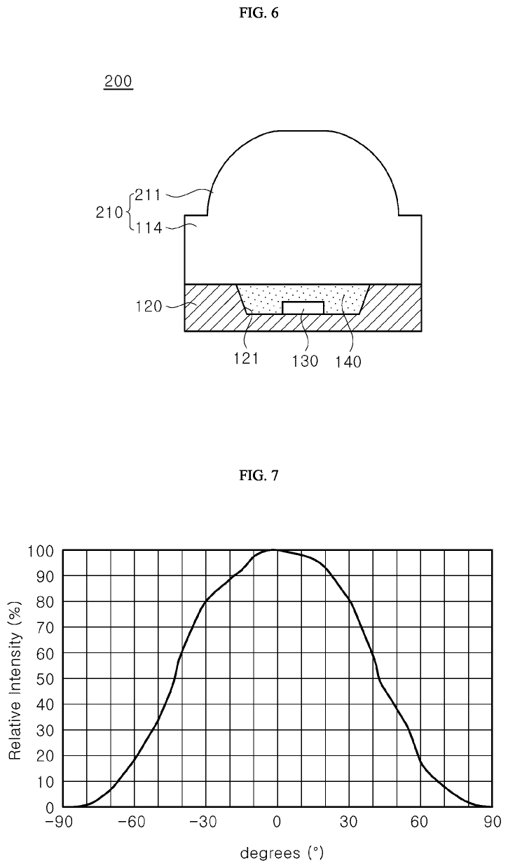

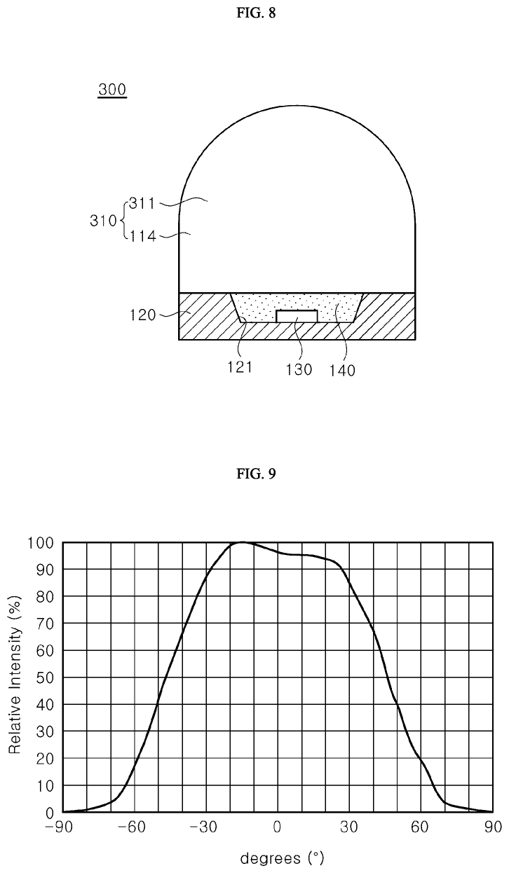

FIG. 6 and FIG. 7 illustrate a light emitting package according to a second embodiment of the present invention. FIG. 6 is a cross-sectional view of the light emitting package according to the second embodiment of the present invention. FIG. 7 is a light distribution graph depicting light distribution of the light emitting package of FIG. 6.

Referring to FIG. 6, the light emitting package 200 according to the second embodiment may include a housing 120, a light source 130, an encapsulation material 140, and a lens 210.

In the light emitting package 200 according to this embodiment, the lens 210 has a different structure from the lens 110 of the light emitting package 100 according to the first embodiment (FIG. 4).

In the light emitting package 200 according to this embodiment, the lens 210 may be formed in a structure having a flat upper surface. According to this embodiment, the first optical region 211 of the lens 210 includes a flat upper surface and a region between the flat upper surface and the second optical region 114 may have a curved surface. According to this embodiment, the curved surface of the first optical region 211 may correspond to the first curved surface 112 and the second curved surface 113 shown in FIG. 2. The flat upper surface of the first optical region 211 may have a greater width than the light source 130. Further, the width of the flat upper surface of the first optical region 211 may be less than a width of an upper region of the cavity 121. Here, the width of the light source 130 refers to a distance between one side and the other side of the light source 130 disposed parallel to the horizontal direction. It can be seen that the luminous intensity is concentrated on the flat surface of the first optical region 211. As such, it is possible to adjust the size of a high luminous intensity region having a luminous intensity of about 90% or more of the peak luminous intensity by adjusting the size of the flat surface of the first optical region 211 on which the luminous intensity is concentrated. For example, the high luminous intensity region may be widened to a region, which is wider than a region of about −10 degrees to about 10 degrees, that is, a region of about 20 degrees or more, as shown in FIG. 5.

Furthermore, the lens 210 of the light emitting package 200 according to this embodiment has a lower height than the lens 110 (see FIG. 4) of the light emitting package 100 according to the first embodiment. More specifically, the first optical region 211 of the lens 210 according to this embodiment has a lower height than the first optical region 111 of the lens 210 (see FIG. 4) according to the first embodiment. In the lens 210 according to this embodiment, the first optical region 211 may have a height of less than about 50% of a diameter of a lower surface of the first optical region 211.

Referring to FIG. 7, a light emitting package 200 according to a second embodiment may have a peak luminous intensity at 0 degrees. In addition, the light emitting package 200 according to the second embodiment may have an angle range of about −45 degrees to about 45 degrees, at which the light emitting package has a luminous intensity of about 50% or more relative to the peak luminous intensity. More specifically, the light emitting package 200 according to the second embodiment may have a light beam angle of about 89.7 degrees. Since the light emitting package 200 according to the second embodiment has a wider beam angle, the light emitting packages 200 according to the second embodiment can realize uniform planar light in a wide area through reinforcing interference with adjacent light emitting apparatuses when a plurality of light emitting packages 200 according to the second embodiment is arranged.

The light emitting package 200 according to the second embodiment may have a luminous intensity of about 90% or more of the peak luminous intensity within an angle of about −20 degrees to about 20 degrees. Furthermore, the light emitting package 100 according to the second embodiment may have an angle range of about −30 degrees to about 30 degrees, at which the light emitting package 100 has a luminous intensity of greater than or equal to about 80% of the peak luminous intensity. That is, the light emitting package 200 according to the second embodiment may emit about 80% or more of light (luminous flux) emitted therefrom at an angle of about 60 degrees relative to the central axis perpendicular to the ground.

FIG. 8 and FIG. 9 illustrate a light emitting package according to a third embodiment of the present invention. FIG. 8 is a cross-sectional view of the light emitting package according to the third embodiment of the present invention. FIG. 9 is a light distribution graph depicting light distribution of the light emitting package of FIG. 8.

Referring to FIG. 8, the light emitting package 300 according to the third embodiment may include a housing 120, a light source 130, an encapsulation material 140, and a lens 310.

In the light emitting package 300 according to this embodiment, the lens 310 has a different structure from the lens 110 (see FIG. 4) of the light emitting package 100 according to the first embodiment.

The lens 310 of the light emitting package 300 according to this embodiment has the same height as the lens 110 (see FIG. 4) of the light emitting package 100 according to the first embodiment. However, referring to FIG. 8, in the lens 310 of the light emitting package 300 according to this embodiment, the lower end of the first optical region 311 may have the same diameter as the upper end of the second optical region 114. Here, the height of the first optical region 311 may be about 0.5 times the diameter of the lower end thereof. For example, the lower end of the first optical region 311 may have the same diameter as the upper end of the second optical region 114. As such, although the lens 310 according to this embodiment may have the same total height as the lens 110 (see FIG. 4) according to the first embodiment, the lens 310 according to this embodiment may have a greater thickness due to a greater diameter of the first optical region 311. Here, the thickness of the first optical region 311 refers to a thickness in a horizontal direction parallel to the lower surface of the first optical region 311.

A light emitting package 300 according to a third embodiment may have a peak luminous intensity within an angle other than 0 degrees. Referring to FIG. 9, the peak luminous intensity may be obtained within an angle of about −30 degrees and about 30 degrees. Furthermore, the light emitting package 300 according to the third embodiment may have a luminous intensity of about 50% or more of the peak luminous intensity within an angle of about −50 degrees to about 50 degrees. More specifically, the light emitting package 300 according to the third embodiment has a beam angle of about 94.1 degrees.

In addition, the light emitting package 300 according to the third embodiment may have a luminous intensity of about 80% or more of the peak luminous intensity within an angle of about −40 degrees to about 40 degrees. That is, the light emitting package 300 according to the third embodiment emits about 80% or more of the luminous flux within an angle of about 80 degrees relative to a central axis (vertical center axis) perpendicular to a lower surface thereof. That is, the luminous intensity of the light emitting package 300 according to the third embodiment may be greater than or equal to about 80% of the luminous flux within an angle of about 80 degrees relative to the vertical center axis. In addition, the luminous intensity of the light emitting package 300 according to the third embodiment may be about 90% or more of the luminous flux within a region between about −30 degrees and about 30 degrees. As such, the light emitting package 300 according to the third embodiment may have a uniform luminous intensity over a larger area. Accordingly, the light emitting package 300 according to the third embodiment can reduce design difficulty of a light emitting apparatus having uniform luminous intensity on a single plane, thereby facilitating implementation of the light emitting apparatus.

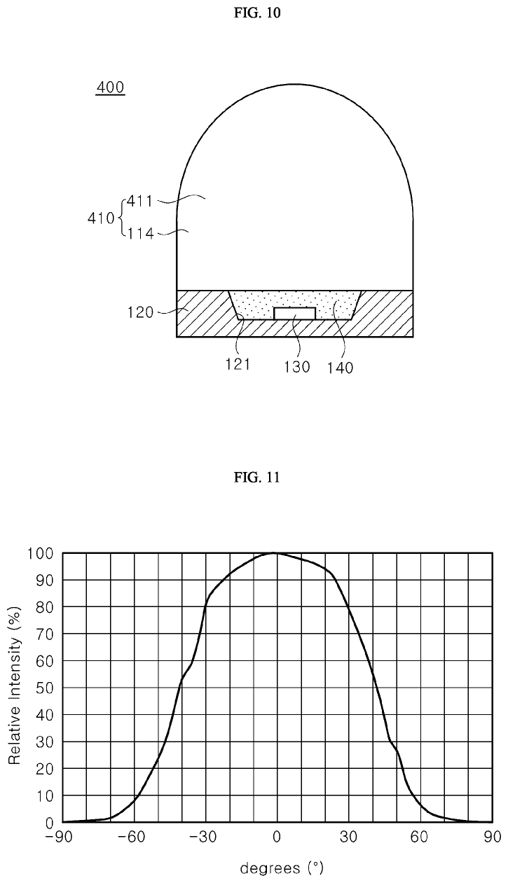

FIG. 10 and FIG. 11 illustrate a light emitting package according to a fourth embodiment of the present invention. FIG. 10 is a cross-sectional view of the light emitting package according to the fourth embodiment of the present invention. FIG. 11 is a light distribution graph depicting light distribution of the light emitting package of FIG. 10.

Referring to FIG. 10, the light emitting package 400 according to the fourth embodiment may include a housing 120, a light source 130, an encapsulation material 140, and a lens 410.

The light emitting package 400 according to this embodiment has a different structure from the lens 310 of the light emitting package 300 (see FIG. 3) according to the third embodiment.

Referring to FIG. 10, like the lens 310 of the light emitting package 300 (see FIG. 3) according to the third embodiment, the lens 410 of the light emitting package 400 according to this embodiment may be formed such that the entire lower surface of the first optical region 411 contacts the entire upper surface of the second optical region 114. The lower end of the first optical region 411 may have the same diameter as the upper end of the second optical region 114. In addition, the upper and lower ends of the second optical region 114 may have the same diameter. However, the lens 410 of the light emitting package 400 according to this embodiment has a greater height than the lens 310 of the light emitting package 300 (see FIG. 8) according to the third embodiment. More specifically, the lens 410 according to this embodiment may include a first optical region 411 having a greater height than the first optical region 311 of the lens 310 (see FIG. 8) according to the third embodiment. In addition, the radius of the lower end of the first optical region 411 may be different from the height of the first optical region 411. For example, the height of the first optical region 411 may be greater than the radius of the lower end thereof.

Further, the first optical region 411 of the light emitting package 400 according to the fourth embodiment may have different radii of curvature in different regions. In one example, the first optical region 411 of the light emitting package 400 may have a smaller radius of curvature in an upper region thereof than in a lower region thereof. The first optical region 411 may have a radius of curvature gradually decreasing in an upward direction. With this structure, the light emitting package 400 according to the fourth embodiment can focus light to an angle of 0 degrees or at an angle close to 0 degrees. That is, the light emitting package 400 according to the fourth embodiment can emit light to be concentrated in an upward direction in a region at or near the vertical center axis.

Referring to FIG. 11, the light emitting package 400 according to the fourth embodiment may have a peak luminous intensity within an angle between about −10 degrees and about 10 degrees. For example, the light emitting package 400 according to the fourth embodiment may have a peak luminous intensity at 0 degrees placed on a vertical centerline of the light source 410.

Further, the light emitting package 400 according to the fourth embodiment may have a luminous intensity of about 50% or more of the peak luminous intensity within an angle of about −45 degrees to about 45 degrees. More specifically, the light emitting package 400 according to the fourth embodiment may have a beam angle of about 90 degrees.

The light emitting package 400 according to the fourth embodiment can concentrate light in a narrow region such that light can be concentrated in a target region when a plurality of light emitting packages is arranged, thereby realizing a light emitting apparatus with high luminance.

Further, the light emitting package 400 according to the fourth embodiment may have a luminous intensity of about 80% or more of the peak luminous intensity within an angle of about −30 degrees to about 30 degrees. In other words, the light emitting package 400 according to the fourth embodiment may have a luminous intensity of about 80% or more of the luminous flux at an angle of about 60 degrees relative to a center axis perpendicular to a lower surface thereof.

Referring to FIG. 5, FIG. 7, FIG. 9, and FIG. 11, the light emitting packages 100, 200, 300, 400 according to the first to fourth embodiments including the lenses 110, 210, 310, 410 respectively have a light beam angle of less than about 120 degrees, specifically less than about 95 degrees. That is, the lenses 110, 210, 310, 410 according to the embodiments of the invention can narrow the beam angle of the light emitting packages 100, 200, 300, 400, as compared with the light source 130 mounted in the housing 120. Furthermore, the light emitting package 300 according to the third embodiment has a light beam angle of about 90 degrees or more, whereas the light emitting packages 100, 200, 400 according to the first, second, and fourth embodiments have a light beam angle of less than about 90 degrees. That is, the lenses 110, 210, 410 according to the first, second, and fourth embodiments can adjust the beam angle of the light emitting packages 100, 200, 400 to be less than about 90 degrees.

The light emitting package 100 according to the first embodiment shown in FIG. 4 and the light emitting package 200 according to the second embodiment shown in FIG. 6 include the lenses 110, 210 having similar structures. However, the lens 110 of the light emitting package 100 according to the first embodiment has a greater height than the lens 210 of the light emitting package 200 according to the second embodiment.

Comparing the light distribution graphs of FIG. 5 and FIG. 7, the light emitting package 100 according to the first embodiment, in which the lens has a greater height, has a narrower beam angle than the light emitting package 200 according to the second embodiment.

In addition, the light emitting package 400 according to the fourth embodiment shown in FIG. 10 and the light emitting package 300 according to the third embodiment shown in FIG. 8 include the lenses 310, 410 having similar structures. However, the lens 410 of the light emitting package 400 according to the fourth embodiment has a greater height than the lens 310 of the light emitting package 300 according to the third embodiment. Comparing the light distribution graphs of FIG. 9 and FIG. 11, the light emitting package 400 according to the fourth embodiment, in which the lens has a greater height, has a narrower beam angle than the light emitting package 300 according to the third embodiment.

In addition, the light emitting package 400 according to the fourth embodiment shown in FIG. 10 includes the lens 410 having a greater height than the lens of the light emitting package 100 according to the first embodiment shown in FIG. 4. Comparing the light distribution graphs of FIG. 5 and FIG. 11, the light emitting package 400 according to the fourth embodiment, in which the lens has a greater height, has a narrower beam angle than the light emitting package 100 according to the first embodiment.

Comparing the beam angles of the light emitting packages 100, 200, 300, 400 depending respectively on the heights of the lenses 110, 210, 310, 410 through the light distribution graphs of FIG. 5, FIG. 7, FIG. 9, and FIG. 11, it can be seen that the beam angles of the light emitting packages 100, 200, 300, 400 respectively decrease as the heights of the lens 110, 210, 310, 410 increase. That is, the beam angle of the light emitting package can be adjusted according to the height of the first optical region of the lens and the beam angle of the light emitting package can be decreased by increasing the height of the first optical region of the lens.

The light emitting package 300 according to the third embodiment shown in FIG. 8 includes the first optical region 311 having a greater maximum diameter than the first optical region of the light emitting package 100 according to the first embodiment shown in FIG. 4.

When the diameter of the lower end of the first optical region changes without change in the height of the first optical region, the area and the curvature of the outer surface of the first optical region can be changed. For example, when the diameter of the lower end of the first optical region increases, the area of the outer surface of the first optical region increases and the curvature thereof decreases. That is, as the diameter of the first optical region increases, the area of the light exit surface 118 of the lens increases and the curvature thereof decreases. Therefore, the light emitting package 100 according to the first embodiment has a smaller beam angle than the light emitting package 300 according to the third embodiment, which includes the first optical region 311 having a greater diameter.

Comparing the light distribution graphs shown in FIG. 5 and FIG. 9, the light emitting package 300 according to the third embodiment has a wider beam angle than the light emitting package 100 according to the first embodiment. Accordingly, the beam angle of the light emitting package can be increased as the maximum diameter of the first optical region of the lens increases. In other words, the beam angle of the light emitting package can be decreased by decreasing the maximum diameter of the first optical region of the lens.

In addition, the light emitting packages 300, 400 according to the third and fourth embodiments shown in FIG. 8 and FIG. 10 include the first optical regions 311, 411 each having a greater maximum diameter than those of the light emitting packages 100, 200 according to the first and second embodiments shown in FIG. 4 and FIG. 6.

Comparing the light distribution graphs shown in FIG. 5 and FIG. 7 with the light distribution graphs shown in FIG. 9 and FIG. 11, it can be seen that the light emitting packages 300, 400 according to the third and fourth embodiments have more uniform luminous intensity at an angle range of about −30 degrees to about 30 degrees than the light emitting packages 100, 200 according to the first and second embodiments. That is, as the maximum diameter of the first optical region of the lens increases, luminous intensity uniformity of the light emitting package is improved at an angle range of about −30 degrees to about 30 degrees.

Comparing the light emitting package 100 according to the first embodiment with the light emitting package 400 according to the fourth embodiment, although the light emitting package 400 according to the fourth embodiment, in which the lens has a greater height, has a narrower beam angle than the light emitting package 100 according to the first embodiment, there is not much difference therebetween. As such, although the lens 110 according to the first embodiment has a lower height than the lens 410 according to the fourth embodiment, the beam angle of the light emitting package may be adjusted similarly to the lens 410 according to the fourth embodiment. That is, the lens including the first optical region having a smaller maximum diameter than the second optical region thereof can efficiently narrow the beam angle of the light emitting package through a minimal increase in height. Thus, the light emitting packages 100, 200 according to the first and second embodiments can have a predetermined narrow range of light beam angles even with a lower height than the light emitting packages 300, 400 according to the third and fourth embodiments. For example, a target beam angle of the light emitting package may be less than about 90 degrees.

As such, the lenses 110, 210, 310, 410 according to the above embodiments and the light emitting packages 100, 200, 300, 400 respectively including the lenses 110, 210, 310, 410 can focus light into a predetermined light emission region through the lenses 110, 210, 310, 410, thereby realizing a narrow beam angle. As such, since the lenses 110, 210, 310, 410 and the respective light emitting packages 100, 200, 300, 400 according to the embodiments of the present invention can focus light emitted from the light source 130 into a predetermined light emission region, it is possible to improve luminance of lighting devices and display devices including the same. Thus, the lenses 110, 210, 310, 410 according to these embodiments and light emitting apparatuses including the same may be applied to devices that require high luminance and low light interference over a certain area, such as vehicular headlamps and the like.

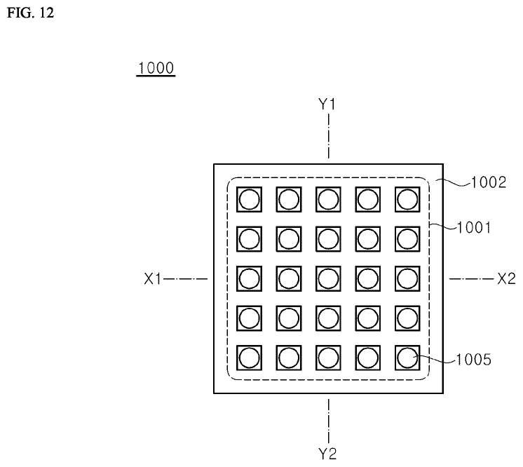

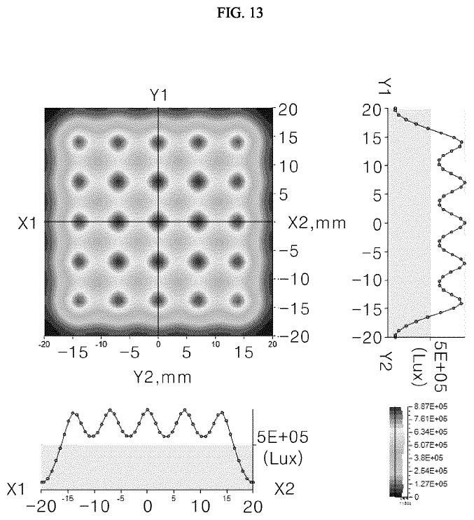

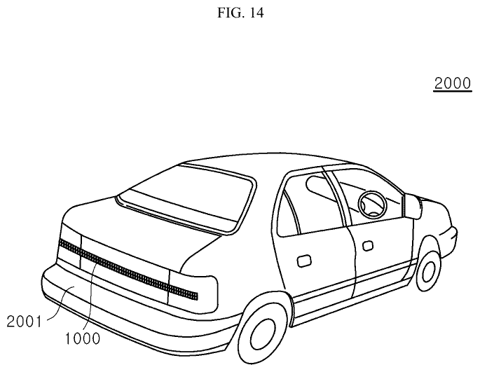

FIG. 12 and FIG. 13 illustrate a light emitting apparatus according to an embodiment of the present invention.

FIG. 12 is a plan view of the light emitting apparatus according to the embodiment of the present invention. FIG. 13 shows simulation results of illuminance of the light emitting apparatus shown in FIG. 12.

The light emitting apparatus 1000 according to this embodiment includes a light emitting package array 1001. The light emitting package array 1001 may be disposed on a support 1002. The support 1002 on which the light emitting package array 1001 is mounted may be a printed circuit board. The support 1002 may be formed with a conductive pattern electrically connected to the light emitting package array 1001.

The light emitting package array 1001 includes a plurality of light emitting packages 1005 arranged in at least a column and at least a row. In this structure, the light emitting packages 1005 may be disposed at certain predetermined intervals. A distance between light emitting packages 1005 of a light emitting package array 1001 may be determined based on the beam angle of the light emitting packages 1005. For example, the distance between the light emitting packages 1005 may be designed such that the luminous intensity in an overlapping region of light emitted from at least two light emitting packages 1005 is greater than or equal to about 60% of the peak luminous intensity of the light emitting package array 1001. In addition, the distance between the light emitting packages 1005 may be designed such that illuminance and/or luminance in the overlapping region of light emitted from the at least two light emitting packages 1005 are greater than or equal to about 60% of the peak values of illuminance and/or luminance of the light emitting package array 1001. That is, in the light emitting package array 1001 according to this embodiment, the luminous intensity, illuminance and/or luminance in a region between the light emitting packages 1005 are greater than or equal to about 60% of the peak values of luminous intensity, illuminance, and/or luminance of the light emitting package array 1001. Further, in order to maintain the luminous intensity, illuminance, and/or luminance of the overlapping light of the light emitting packages 1005, the distance between the light emitting packages 1005 may be greater than or equal to about 2 times and less than about 10 times the width of the light emitting packages 1005. As used herein, the overlapping light means that light emitted from at least two light emitting packages 1005 overlaps each other. For example, in this embodiment, when the light emitting packages 1005 have a size of about 1.5 mm, the light emitting packages 1005 may be arranged at intervals of about 3 mm to about 15 mm.

The light emitting packages 1005 included in the light emitting apparatus 1000 according to this embodiment may include one of the light emitting packages according to the first to fourth embodiments 100, 200, 300, 400 (see FIG. 4 to FIG. 11).

FIG. 13 shows illuminance raster charts and illuminance graphs of simulation results of illuminance of the light emitting apparatus 1000 shown in FIG. 12.

In this embodiment, both illuminance uniformity measured in the range of about −15 mm to about 15 mm corresponding to one row X1-X2 of the light emitting package array 1001 and illuminance uniformity measured in the range of about −15 mm to about 15 mm corresponding to one column Y1-Y2 may be greater than or equal to about 60%. Specifically, each of the illuminance uniformity values is about 67%.

Further, in the range of about −15 mm to about 15 mm, the light emitting apparatus may have a difference of less than about 40% between the maximum illuminance and the minimum illuminance based on the maximum illuminance

In addition, referring to FIG. 13, the light emitting apparatus 1000 may have a plurality of peak points and a plurality of valley points. Each of the plurality of peak points may correspond to a maximum luminous intensity point of each of the plurality of light emitting packages 1005. Further, each of the plurality of valley points may correspond to an overlapping point of light emitted from neighboring light emitting packages 1005. That is, each peak point may correspond to light having the maximum luminous intensity of each of the light emitting packages 1005 and Each valley point may correspond to overlapping light between neighboring light emitting packages 1005. In this embodiment, the value of the valley point may be higher than the luminous intensity of at least a light emitting package 1005 at an angle range of about −60 degrees or less or about 60 degrees or more. The light emitting apparatus 1000 according to this embodiment provides less deviation in illuminance and/or or luminance even with a fewer number of light emitting packages 1005, thereby facilitating design of a surface light source with high uniformity in illuminance and/or luminance.

Although the light emitting apparatus 1000 according to this embodiment has been described as including one of the light emitting packages 100, 200, 300, 400 (see FIG. 4 to FIG. 11) according to the first to fourth embodiments, the light emitting apparatus 1000 according to this embodiment is not limited thereto. That is, the light emitting apparatus 1000 according to this embodiment may include at least two light emitting packages among the light emitting packages according to the first to fourth embodiments 100, 200, 300, 400 (see FIG. 4 to FIG. 11). Furthermore, the light emitting apparatus 1000 according to this embodiment may include one or both of the light emitting packages 100, 200 (see FIG. 4 to FIG. 7) according to the first and second embodiments, in which the beam angle can be reduced through minimal adjustment in height.

For example, in the light emitting apparatus 1000, light emitting packages having a relatively wide beam angle are disposed in a central region and light emitting packages having a relatively narrow beam angle are disposed in an outer region of the central region. With this arrangement, the light emitting apparatus 1000 can reduce a luminance difference between the central region on which light is relatively focused and the outer region where light is less focused than the center region. Furthermore, in order to reduce the luminance difference between the regions, a difference in beam angle between the light emitting packages disposed in the central region and the light emitting packages disposed in the outer region may be greater than or equal to about 5 degrees and less than about 20 degrees.

In another example, in the light emitting apparatus 1000, light emitting packages having relatively low center beam candlepower (CBCP) are disposed in the central region and light emitting packages having relatively high center beam candlepower are disposed in the outer region. With such an arrangement, the light emitting apparatus 1000 can improve a difference in illuminance and/or luminance between regions. In addition, the light emitting apparatus 1000 may have a difference of less than about 5% in luminous intensity, illuminance, and/or luminance between a plurality of peak points by a plurality of light emitting packages. Accordingly, the light emitting apparatus 1000 may have a difference of less than about 5% in luminous intensity, illuminance, and/or luminance between a peak point in a central region and a peak point in a peripheral region.

FIG. 14 is an exemplary view of a vehicle including a light emitting apparatus according to an embodiment of the present invention. Here, the light emitting apparatus 1000 may include a vehicular lamp, such as a turn signal lamp, a headlight, and the like.

According to this embodiment, the light emitting apparatus 1000 applied to a vehicle 2000 may include the light emitting packages 100, 200, 300, 400 described with reference to FIG. 4 to FIG. 11. Alternatively, the light emitting apparatus 1000 may be the light emitting apparatus 1000 shown in FIG. 12, which includes a plurality of light emitting packages 100, 200, 300, 400 described with reference to FIG. 4 to FIG. 11.

The vehicle 2000 includes a main body 2001 and the light emitting apparatus 1000 mounted on the main body 2001. The light emitting apparatus 1000 for vehicles requires control of a luminous region for directional indication or adjustment of a projection region.

According to this embodiment, the light emitting apparatus 1000 may be provided with a plurality of light emitting packages 1005 arranged thereon. In addition, the light emitting apparatus 1000 may control the plurality of light emitting packages 1005 to operate each of the plurality of light emitting packages 1005 separately. Thus, the light emitting apparatus 1000 can easily adjust the luminous region or the projection region by independently controlling the plurality of light emitting packages 1005 with low light interference.

In this embodiment, although both the light emitting apparatus and the light emitting package do not include a wavelength conversion member, it should be understood that the present invention is not limited thereto. Alternatively, the light emitting apparatus may further include a wavelength conversion member. In addition, when the light emitting apparatus includes a plurality of light emitting packages, at least a light emitting package may further include a wavelength converter or may further include a wavelength conversion material dispersed in the encapsulation material 140 or the lens, as in the light emitting apparatus.

Next, additional exemplary embodiments will be described. However, it should be understood that the present invention is not limited to the following additional embodiments.

Example 1: A light emitting apparatus may include: a lens including a light incidence surface through which external light enters the lens and a light exit surface through which the light having entered the lens exits the lens, may include: a first optical region comprising a curved surface having a diameter gradually decreasing from bottom to top; and a second optical region disposed under the first optical region, the second optical region having a constant width from top to bottom and comprising a flat side surface. A maximum diameter of the first optical region may be less than or equal to a maximum diameter of the second optical region. A part or all of a lower surface of the second optical region may constitute the light incidence surface, an outer surface of the first optical region may constitute the light exit surface. Wherein, a light beam angle of light emitted from the lens is less than about 90 degrees.

Example 2: In the light emitting apparatus according to Example 1, the first optical region of the lens may include a first curved surface and a second curved surface disposed between the first curved surface and the second optical region. The first curved surface may include a convexly curved surface having a diameter gradually decreasing from bottom to top. Wherein, the second curved surface may include a concavely curved surface having a diameter gradually increasing from top to bottom.

Example 3: In the light emitting apparatus according to Example 1, the height of the second optical region may be less than the height of the first optical region.

Example 4: In the light emitting apparatus according to Example 1, the height of the second optical region may be less than or equal to about 60% of the height of the first optical region.

Example 5: In the light emitting apparatus according to Example 1, a lower end of an inner surface of the first optical region may have the same diameter as an upper end an inner surface of the second optical region

Example 6: In the light emitting apparatus according to Example 1, the second optical region of the lens may include a light absorbing material or a light reflecting material in at least a region thereof excluding the light incidence surface.

Example 7: In the light emitting apparatus according to Example 1, the first optical region and the second optical region may be integrally formed with each other.

Example 8: In the light emitting apparatus according to Example 1, the first optical region may have an outer shape according to Formula 1:

$$y = a + b \sqrt{c - {x}^{2}} \qquad ( 1 )$$

where x is a position on the lens along the x-axis of the lens, y is the height of the lens depending on the position x, a is the height of the second optical region, b is a ratio of the height of the first optical region to the radius thereof, and \sqrt{c} is the radius of the first optical region.

Example 9: A light emitting apparatus may include: a housing having a cavity open at an upper side thereof; a light source disposed in the cavity of the housing and emitting light; and a lens disposed on the housing and including a light incidence surface through which light emitted from the light source enters the lens and a light exit surface through which the light having entered the lens exits the lens. The lens may include a first optical region comprising a curved surface having a diameter gradually decreasing from bottom to top; and a second optical region disposed under the first optical region, the second optical region having a constant width from top to bottom and comprising a flat side surface. A maximum diameter of the first optical region may be less than or equal to a maximum diameter of the second optical region. A part or all of a lower surface of the second optical region may constitute the light incidence surface. An outer surface of the first optical region may constitute the light exit surface. Wherein, a light beam angle of light emitted from the lens is narrower than a beam angle of light emitted from the light source, the light beam angle of the lens being less than about 90 degrees.

Example 10: In the light emitting apparatus according to Example 9, the first optical region of the light emitting package may include a first curved surface and a second curved surface disposed between the first curved surface and the second optical region. The first curved surface may include a convexly curved surface having a diameter gradually decreasing from bottom to top. In addition, the second curved surface may include a concavely curved surface having a diameter gradually increasing from top to bottom.

Example 11: In the light emitting apparatus according to Example 9, an uppermost end of the first optical region of the lens may be disposed on a vertical line collinear with a center of the light source.

Example 12: In the light emitting apparatus according to Example 9, a height of the first optical region of the lens may be in the range of about 1 times to about 2.5 times a height of the housing.

Example 13: In the light emitting apparatus according to Example 9, a height of the second optical region may be less than a height of the first optical region and greater than a height of the light source.

Example 14: In the light emitting apparatus according to Example 9, the height of the second optical region may be less than or equal to about 60% of the height of the first optical region.

Example 15: In the light emitting apparatus according to Example 9, the height of the second optical region may be greater than or equal to about 6 times and less than about 10 times the height of the light source.

Example 16: In the light emitting apparatus according to Example 9, a lower end of an inner surface of the first optical region may have a substantially same diameter as an upper end of an inner surface of the second optical region.

Example 17: In the light emitting apparatus according to Example 9, the second optical region may include a light absorbing material or a light reflecting material in at least a region thereof excluding the light incidence surface.

Example 18: In the light emitting apparatus according to Example 9, the first optical region and the second optical region may be integrally formed with each other.

Example 19: The light emitting apparatus according to Example 9 may further include a molding region formed in the cavity of the housing and covering the light source. The molding region may be formed of a material allowing transmission of light emitted from the light source therethrough.

Example 20: In the light emitting apparatus according to Example 9, the first optical region may have an outer shape according to Formula 1:

$$y = a + b \sqrt{c - {x}^{2}} \qquad ( 1 )$$

wherein x is a position on the lens along the x-axis of the lens, y is the height of the lens depending on the position x, a is the height of the second optical region, b is a ratio of the height of the first optical region to the radius thereof, and \sqrt{c} is the radius of the first optical region.

Example 21: In the light emitting apparatus according to Example 9, the light beam angle may be an angle range of about −42 degrees to about 42 degrees, at which the light emitting apparatus has a luminous intensity of greater than or equal to about 50% of the peak luminous intensity.

Example 22: In the light emitting apparatus according to Example 9, the beam angle range at which a luminous intensity of greater than or equal to about 80% of the peak luminous intensity may range from-30 degrees to 30 degrees.

Example 23: In the light emitting apparatus according to Example 9, the beam angle range at which a luminous intensity of greater than or equal to about 90% of the peak luminous intensity may range from-20 degrees to 20 degrees.

Example 24: A light emitting apparatus may include: a light emitting package array including a plurality of light emitting packages; and a support on which the light emitting package array is mounted.

Example 25: In the light emitting apparatus according to Examples 9 to 24, the light emitting package array may produce overlapping light, in which light emitted from two adjacent light emitting packages overlap each other. Further, the light emitting package array may have minimum overlapping light between the two adjacent light emitting packages.

Example 26: In the light emitting apparatus according to Example 25, the two adjacent light emitting packages may be arranged such that the overlapping light has a luminous intensity of about 60% or more of a peak luminous intensity of at least one light emitting package.

Example 27: A light emitting package may include: a housing having a cavity open at an upper side thereof; a light source disposed in the cavity of the housing and emitting light; and a lens disposed on the housing and including a light incidence surface through which light emitted from the light source enters the lens and a light exit surface through which the light having entered the lens exits the lens. The lens may include a first optical region comprising a curved surface having a diameter gradually decreasing from bottom to top; and a second optical region disposed under the first optical region, the second optical region having a constant width from top to bottom and comprising a flat side surface. An upper surface of the first optical region may include a flat region. A part or all of a lower surface of the second optical region may constitute the light incidence surface. An outer surface of the first optical region may constitute the light exit surface. In addition, the lens may have a narrower light beam angle than the light source, the light beam angle of the lens being less than about 90 degrees.

Example 28: In the light emitting package according to Example 27, the first optical region may include a first curved surface and a second curved surface disposed between the first curved surface and the second optical region. The first curved surface may include a convexly curved surface having a diameter gradually decreasing from bottom to top. In addition, the second curved surface may include a concavely curved surface having a diameter gradually increasing from top to bottom.

Example 29: In the light emitting package according to Example 27 or 28, a height of the first optical region of the lens may be in the range of about 1 to about 2.5 times a height of the housing.

Example 30: In the light emitting package according to Example 27 to 29, a height of the second optical region may be less than a height of the first optical region and greater than a height of the light source.

Example 31: In the light emitting package according to Example 30, the height of the second optical region may be less than or equal to about 60% of the height of the first optical region.

Example 32: In the light emitting package according to Example 30 or 31, the height of the second optical region may be greater than or equal to about 6 times and less than about 10 times the height of the light source.

Example 33: In the light emitting package according to Example 27 to 31, a lower end of an inner surface of the first optical region may have the same diameter as an upper end of an inner surface of the second optical region.

Example 34: In the light emitting package according to Example 27 to 33, the first optical region and the second optical region may be integrally formed with each other.

Example 35: In the light emitting package according to Example 27 to 34, a flat region of the first optical region of the lens may be larger than a width of the light source and narrower than a width of the cavity.

Example 36: In the light emitting package according to Example 35, a region between the flat region of the first optical region and the second optical region may form a curved surface.

In addition, the curve of the first optical region may have a shape according to Formula 1:

$$y = a + b \sqrt{c - {x}^{2}} \qquad ( 1 )$$

where x is a position on the lens along the x-axis of the lens, y is the height of the lens depending on the position x, a is the height of the second optical region, b is a ratio of the height of the first optical region to the radius thereof, and \sqrt{c} is the radius of the first optical region.

Example 37: In the light emitting package according to Example 27 to 34, the first optical region may have a height of less than about 50% of a diameter of a lower surface of the first optical region.

Example 38: In the light emitting package according to Example 27 to 34, a beam angle at which a luminous intensity of greater than or equal to about 50% of the peak luminous intensity may range from about −45 degrees to about 45 degrees.

Example 39: In the light emitting package according to Example 27 to 34, a beam angle at which a luminous intensity of greater than or equal to about 80% of peak luminous intensity may range from-30 degrees to about 30 degrees.

Example 40: In the light emitting package according to Example 27 to 34, a beam angle at which a luminous intensity of greater than or equal to about 90% of peak luminous intensity may range from about −25 degrees to about 25 degrees.

Example 41: A light emitting apparatus may include: a light emitting package array including a plurality of light emitting packages; and a support on which the light emitting package array is mounted.

Example 42: In the light emitting apparatus according to Example 41, the light emitting package array may produce overlapping light, in which light emitted from two adjacent light emitting packages overlap each other. Further, the light emitting package array may have minimum overlapping light between the two adjacent light emitting packages.

Example 43: In the light emitting apparatus according to Example 41 or 42, the two adjacent light emitting packages may be arranged such that the overlapping light has a luminous intensity of about 60% or more of the peak luminous intensity of at least one light emitting package. Alternatively, the two adjacent light emitting packages may be arranged such that the overlapping light has illuminance and/or luminance of about 60% or more of the peak values of illuminance and/or luminance of at least one light emitting package.

Example 44: A light emitting apparatus may comprise a light emitting package. The light emitting package may include: a housing having a cavity open at an upper side thereof; a light source disposed in the cavity of the housing and emitting light; and a lens disposed on the housing and including a light incidence surface through which light emitted from the light source enters the lens and a light exit surface through which the light having entered the lens exits the lens. The lens may include a first optical region comprising a curved surface having a diameter gradually decreasing from bottom to top; and a second optical region disposed under the first optical region, the second optical region having a constant width from top to bottom and comprising a flat side surface. An upper surface of the first optical region may include a flat region. A part or all of a lower surface of the second optical region may constitute the light incidence surface. An outer surface of the first optical region may constitute the light exit surface. In addition, the lens may have a narrower light beam angle than the light source, the light beam angle of the lens being less than about 90 degrees.

Example 45: In the light emitting apparatus according to Example 44, the first optical region may include a first curved surface and a second curved surface disposed between the first curved surface and the second optical region. The first curved surface may include a convexly curved surface having a diameter gradually decreasing from bottom to top. In addition, the second curved surface may include a concavely curved surface having a diameter gradually increasing from top to bottom.

Example 46: In the light emitting apparatus according to Example 44, a height of the first optical region of the lens may be in the range of about 1 to about 2.5 times a height of the housing.

Example 47: In the light emitting apparatus according to Example 46, a height of the second optical region may be less than a height of the first optical region and greater than a height of the light source.

Example 48: In the light emitting apparatus according to Example 46, the height of the second optical region may be less than or equal to about 60% of the height of the first optical region.

Example 49: In the light emitting apparatus according to Example 47 or 48, the height of the second optical region may be greater than or equal to about 6 times and less than about 10 times the height of the light source.

Example 50: In the light emitting apparatus according to Example 41, a lower end of an inner surface of the first optical region may have the same diameter as an upper end of an inner surface of the second optical region.

Example 51: In the light emitting apparatus according to Example 41 to 49, the first optical region and the second optical region may be integrally formed with each other.

Example 52: In the light emitting apparatus according to Example 41 to 51, a flat region of the first optical region of the lens may be larger than a width of the light source and narrower than a width of the cavity.

Example 53: In the light emitting apparatus according to Example 52, a region between the flat region of the first optical region and the second optical region may form a curved surface.

The curve of the first optical region may have a shape according to Formula 1:

$$y = a + b \sqrt{c - {x}^{2}} \qquad ( 1 )$$

where x is a position on the lens along the x-axis of the lens, y is the height of the lens depending on the position x, a is the height of the second optical region, b is a ratio of the height of the first optical region to the radius thereof, and \sqrt{c} is the radius of the first optical region.

Example 54: In the light emitting apparatus according to Example 41 to 53, the first optical region may have a height of less than about 50% of a diameter of a lower surface of the first optical region.

Example 55: In the light emitting apparatus according to Example 41 to 54, an angle range of about −45 degrees to about 45 degrees, at which the light emitting package has a luminous intensity of greater than or equal to about 50% of the peak luminous intensity.

Example 56: In the light emitting apparatus according to Example 41 to 54, the light emitting package may have an angle range of about −30 degrees to about 30 degrees, at which the light emitting package has a luminous intensity of greater than or equal to about 80% of the peak luminous intensity.

Example 57: In the light emitting apparatus according to Example 41 to 54, the light emitting package may have an angle range of about −25 degrees to about 25 degrees, at which the light emitting package has a luminous intensity of greater than or equal to about 90% of the peak luminous intensity.

Example 58: A light emitting apparatus may include: a light emitting package array including a plurality of light emitting packages; and a support on which the light emitting package array is mounted.

Example 59: In the light emitting apparatus according to Example 58, the light emitting package array may produce overlapping light, in which light emitted from two adjacent light emitting packages overlap each other. Further, the light emitting package array may have minimum overlapping light between the two adjacent light emitting packages.

Example 60: In the light emitting apparatus according to Example 59, the two adjacent light emitting packages may be arranged such that the overlapping light has a luminous intensity of about 60% or more of the peak luminous intensity of at least one light emitting package.

Example 61: A light emitting apparatus may comprise: a housing having a cavity open at an upper side thereof; a light source disposed in the cavity of the housing and emitting light; and a lens disposed on the housing and including a light incidence surface through which light emitted from the light source enters the lens and a light exit surface through which the light having entered the lens exits the lens. The lens may include a first optical region comprising a curved surface having a diameter gradually decreasing from bottom to top; and a second optical region disposed under the first optical region, the second optical region having a constant width from top to bottom. A lower surface of the first optical region may have the same diameter as an upper surface of the second optical region. A part or all of a lower surface of the second optical region may constitute the light incidence surface. An outer surface of the first optical region may constitute the light exit surface. The first optical region may have a different radius of curvature between an upper region and a lower region thereof. In addition, the lens may have a narrower light beam angle than the light source, the light beam angle of the lens being less than about 100 degrees.

Example 62: In the light emitting apparatus according to Example 61, the height of the first optical region may be about 0.5 times the diameter of the first optical region.

Example 63: In the light emitting apparatus according to Example 61 to 62, a height of the first optical region of the lens may be in the range of about 1 to about 2.5 times a height of the housing.

Example 64: In the light emitting apparatus according to Example 61 to 63, a height of the second optical region may be less than a height of the first optical region and greater than a height of the light source.

Example 65: In the light emitting apparatus according to Example 64, the height of the second optical region may be less than or equal to about 60% of the height of the first optical region.

Example 66: In the light emitting apparatus according to Example 64 or 65, the height of the second optical region may be greater than or equal to about 6 times and less than about 10 times the height of the light source.

Example 67: In the light emitting apparatus according to Example 61 to 66, the first optical region and the second optical region may be integrally formed with each other.

Example 68: In the light emitting apparatus according to Example 61 to 67, a flat region of the first optical region of the lens may be larger than a width of the light source and narrower than a width of the cavity.

Example 69: In the light emitting apparatus according to Example 61 to 68, the first optical region may have a height of less than about 50% of a diameter of a lower surface of the first optical region.

Example 70: In the light emitting apparatus according to Example 61 to 69, the light emitting package may have an angle range of about −50 degrees to about 50 degrees, at which the light emitting package has a luminous intensity of greater than or equal to about 50% of the peak luminous intensity.

Example 71: Int the light emitting apparatus according to Example 61 to 69, the light emitting package may have an angle range of about −40 degrees to about 40 degrees, at which the light emitting package has a luminous intensity of greater than or equal to about 80% of the peak luminous intensity.

Example 72: In the light emitting apparatus according to Example 61 to 71, the light emitting package may have an angle range of about −30 degrees to about 30 degrees, at which the light emitting package has a luminous intensity of greater than or equal to about 90% of the peak luminous intensity.

Example 73: The light emitting apparatus according to Example 61 to 72 may include: a light emitting package array including a plurality of light emitting packages; and a support on which the light emitting package array is mounted.

Example 74: In the light emitting apparatus according to Example 73, the light emitting package array may produce overlapping light, in which light emitted from two adjacent light emitting packages overlap each other. Further, the light emitting package array may have minimum overlapping light between the two adjacent light emitting packages.

Example 75: In the light emitting apparatus according to Example 73 or 74, the two adjacent light emitting packages may be arranged such that the overlapping light has a luminous intensity of about 60% or more of the peak luminous intensity of at least one light emitting package.

Example 76: A light emitting apparatus may comprise: a housing having a cavity open at an upper side thereof; a light source disposed in the cavity of the housing and emitting light; and a lens disposed on the housing and including a light incidence surface through which light emitted from the light source enters the lens and a light exit surface through which the light having entered the lens exits the lens. The lens may include a first optical region comprising a curved surface having a diameter gradually decreasing from bottom to top; and a second optical region disposed under the first optical region, the second optical region having a constant width from top to bottom. A lower surface of the first optical region may have the same diameter as an upper surface of the second optical region. A part or all of a lower surface of the second optical region may constitute the light incidence surface. An outer surface of the first optical region may constitute the light exit surface. The first optical region may have a different radius of curvature between an upper region and a lower region thereof. In addition, the lens may have a narrower light beam angle than the light source, the light beam angle of the lens being less than about 100 degrees.

Example 77: In the light emitting apparatus according to Example 76, the height of the first optical region may be about 0.5 times the diameter of the first optical region.

Example 78: In the light emitting apparatus according to Example 77, a height of the first optical region of the lens may be in the range of about 1 to about 2.5 times a height of the housing.

Example 79: In the light emitting apparatus according to Example 76 to 78, a height of the second optical region may be less than a height of the first optical region and greater than a height of the light source.

Example 80: In the light emitting apparatus according to Example 76 to 79, the height of the second optical region may be less than or equal to about 60% of the height of the first optical region.

Example 81: In the light emitting apparatus according to Example 76 to 80, the height of the second optical region may be greater than or equal to about 6 times and less than about 10 times the height of the light source.

Example 82: In the light emitting apparatus according to Example 76 to 81, the first optical region and the second optical region may be integrally formed with each other.

Example 83: In the light emitting apparatus according to Example 76 to 82, a flat region of the first optical region of the lens may be larger than a width of the light source and narrower than a width of the cavity.

Example 84: In the light emitting apparatus according to Example 76 to 83, the first optical region may have a height of less than about 50% of a diameter of a lower surface of the first optical region.

Example 85: In the light emitting apparatus according to Example 76 to 84, an angle range of about −50 degrees to about 50 degrees, at which the light emitting package has a luminous intensity of greater than or equal to about 50% of the peak luminous intensity.

Example 86: In the light emitting apparatus according to Example 76 to 84, an angle range of about −40 degrees to about 40 degrees, at which the light emitting package has a luminous intensity of greater than or equal to about 80% of the peak luminous intensity.

Example 87: In the light emitting apparatus according to Example 76 to 84, an angle range of about −30 degrees to about 30 degrees, at which the light emitting package has a luminous intensity of greater than or equal to about 90% of the peak luminous intensity.

Example 88: The light emitting apparatus according to Example 76 to 87, further may include: a light emitting package array including a plurality of light emitting packages; and a support on which the light emitting package array is mounted.

Example 89: In the light emitting apparatus according to Example 88, the light emitting package array may produce overlapping light, in which light emitted from two adjacent light emitting packages overlap each other. Further, the light emitting package array may have minimum overlapping light between the two adjacent light emitting packages.

Example 90: In the light emitting apparatus according to Example 89, the two adjacent light emitting packages may be arranged such that the overlapping light has a luminous intensity of about 60% or more of the peak luminous intensity of at least one light emitting package.

Example 91: A light emitting apparatus may comprise: a light emitting package array including a plurality of light emitting packages; and a support on which the light emitting package array is mounted. Each of the plurality of the light emitting packages may include a housing having a cavity open at an upper side thereof; a light source disposed in the cavity of the housing and emitting light; and a lens disposed on the housing and including a light incidence surface through which light emitted from the light source enters the lens and a light exit surface through which the light having entered the lens exits the lens. The light emitting package array may include a plurality of light emitting packages arranged in at least a column and at least a row. In this structure, the light emitting packages may be disposed at certain predetermined intervals. For example, the light emitting packages may be arranged such that the luminous intensity of overlapping light of at least two light emitting packages is greater than or equal to about 60% of the peak luminous intensity of the light emitting package array. Alternatively, the two adjacent light emitting packages may be arranged such that the overlapping light has illuminance and/or luminance of about 60% or more of the peak values of illuminance and/or luminance of at least one light emitting package.

Example 92: The light emitting apparatus according to Example 91 may have different illuminance in different regions relative to a light emitting surface thereof. A wavelength of light emitted from the light emitting surface may have a plurality of peak points and a plurality of valley points.

Example 93: In the light emitting apparatus according to Example 91, the plurality of peak points may correspond to peak luminous intensity points of the plurality of light emitting packages, respectively.

Example 94: In the light emitting apparatus according to Example 91, each of the plurality of valley points may correspond to an overlapping point of light emitted from neighboring light emitting packages.

Example 95: In the light emitting apparatus according to Example 91, a valley point of the overlapping point may have a luminous intensity of about 60% or more of the peak luminous intensity of the light emitting package array. That is, illuminance and/or luminance at the valley point of the overlapping point of the light emitting apparatus may be greater than or equal to about 60% of the peak values of illuminance and/or luminance of the light emitting package array.

Example 96: In the light emitting apparatus according to Example 91, a difference in beam angle between a light emitting package disposed in the central region of the light emitting apparatus and a light emitting package disposed in the peripheral region may be greater than or equal to about 5 degrees and less than about 20 degrees.

Example 97: In the light emitting apparatus according to Example 96, a difference between luminous intensity at a peak point in the center region and luminous intensity at a peak point in the peripheral region may be less than about 5%. That is, the light emitting apparatus may have a difference of less than about 5% in illuminance and/or luminance between the peak point in the center region and the peak point in the peripheral region.

The light emitting package disposed in the center region of the light emitting apparatus may have a lower luminous intensity than the light emitting package disposed in the peripheral region.

Although some embodiments have been described herein with reference to the accompanying drawings, it should be understood that the foregoing embodiments are provided for illustration only and are not to be in any way construed as limiting the scope of the present invention. The scope of the present invention should be defined by the appended claims and equivalents thereto.

What is claimed is:

1. A light emitting apparatus, comprising:
a housing having a cavity open at an upper side thereof;
a light source disposed in the cavity of the housing and emitting light; and
a lens disposed on the housing and including a light incidence surface and a light exit surface, the lens comprising:
a first optical region comprising a curved surface having a diameter gradually decreasing from bottom to top; and
a second optical region disposed under the first optical region, the second optical region having a flat side surface,
wherein a maximum diameter of the first optical region is less than or equal to a maximum diameter of the second optical region, and
wherein a light beam angle of the lens is narrower than a light beam angle of the light source, and the light beam angle of the lens is less than 90 degrees.

2. The light emitting apparatus according to claim 1, wherein
the curved surface of the first optical region includes a first curved region and a second curved region disposed between the first curved region and the second optical region,
the first curved region includes a convexly curved region having a diameter gradually decreasing from bottom to top, and
the second curved region includes a concavely curved region having a diameter gradually increasing from top to bottom.

3. The light emitting apparatus according to claim 1, wherein an uppermost end of the first optical region of the lens is disposed on a vertical line collinear with a center of the light source.

4. The light emitting apparatus according to claim 1, wherein a height of the lens is in a range of 1 times to 2.5 times a height of the housing.

5. The light emitting apparatus according to claim 1, wherein a height of the second optical region is less than a height of the first optical region and greater than a height of the light source.

6. The light emitting apparatus according to claim 5, wherein the height of the second optical region is less than or equal to 60% of the height of the first optical region.

7. The light emitting apparatus according to claim 5, wherein the height of the second optical region is greater than or equal to 6 times and less than 10 times the height of the light source.

8. The light emitting apparatus according to claim 1, wherein a lower end of an inner surface of the first optical region has a substantially same diameter as an upper end of an inner surface of the second optical region.

9. The light emitting apparatus according to claim 1, wherein the second optical region includes a light absorbing material or a light reflecting material in at least a region thereof excluding the light incidence surface.

10. The light emitting apparatus according to claim 1, wherein the first optical region and the second optical region are integrally formed with each other.

11. The light emitting apparatus according to claim 9, further comprising:
a molding region disposed in the cavity of the housing and covering the light source.

12. The light emitting apparatus according to claim 1, wherein the first optical region has an outer shape according to Formula 1:
$$y = a + b \sqrt{c - {x}^{2}} \qquad ( 1 )$$
where x is a position on the lens along the x-axis of the lens, y is a height of the lens depending on the position x, a is a height of the second optical region, b is a ratio of a height of the first optical region to a radius thereof, and \sqrt{c} is the radius of the first optical region.

13. A light emitting apparatus, comprising:
a light emitting package array comprising a plurality of light emitting packages; and
a support on which the light emitting package array is disposed,
at least one of the plurality of light emitting packages including:
a housing having a cavity open at an upper side thereof;
a light source disposed in the cavity of the housing and emitting light; and
a lens disposed on the housing and including a light incidence surface and a light exit surface, wherein the lens includes:
a first optical region including a curved region having a diameter gradually decreasing from bottom to top; and
a second optical region disposed under the first optical region, the second optical region having a flat side surface,
wherein a maximum diameter of the first optical region is less than or equal to a maximum diameter of the second optical region, and
wherein at least one of the plurality of light emitting packages has a light beam angle narrower than the light source, and the light beam angle is less than 90 degrees.

14. The light emitting apparatus according to claim 13, wherein a height of the first optical region of the lens is in a range of 1 times to 2.5 times a height of the housing.

15. The light emitting apparatus according to claim 13, wherein a height of the second optical region is less than a height of the first optical region and greater than a height of the light source.

16. The light emitting apparatus according to claim 15, wherein the height of the second optical region is less than or equal to 60% of the height of the first optical region.

17. The light emitting apparatus according to claim 15, wherein the height of the second optical region of the lens is greater than or equal to 6 times and less than 10 times the height of the light source.

18. The light emitting apparatus according to claim 13, wherein the second optical region comprises a light absorbing material or a light reflecting material in at least a region thereof excluding the light incidence surface.

19. The light emitting apparatus according to claim 13, wherein the first optical region has an outer shape according to Formula 1:
$$y = a + b \sqrt{c - {x}^{2}} \qquad ( 1 )$$
where x is a position on the lens along the x-axis of the lens, y is a height of the lens depending on the position x, a is a height of the second optical region, b is a ratio of a height of the first optical region to a radius thereof, and \sqrt{c} is the radius of the first optical region.

20. A light emitting apparatus, comprising:
a light emitting package array comprising a plurality of light emitting packages; and
a support on which the light emitting package array is disposed,
at least one of the plurality of light emitting packages including:
a housing having a cavity open at an upper side thereof;
a light source disposed in the cavity of the housing and emitting light; and
a lens disposed on the housing and including a light incidence surface and a light exit surface,
wherein the lens includes:
a first optical region including a curved region having a diameter gradually decreasing from bottom to top; and
a second optical region disposed under the first optical region, and having a flat side surface,
wherein two light emitting sources of the plurality of light emitting sources adjacent to each other have an overlapped light, and
wherein the overlapped light has a minimum intensity in a region between the two light emitting sources.
